(19) United States
(12) Patent Application Publication
(10) Pub. No.: US 2010/0163097 A1
(43) Pub. Date: Jul. 1, 2010

(54) SOLAR CELL MODULE WITH CONCAVITY SURFACE

(75) Inventors: YING-CHIEH LU, Chu-Nan (TW); NAI-WEN ZHANG, Chu-Nan (TW); KUO-FENG CHIANG, Chu-Nan (TW); JYH-LONG CHERN, Chu-Nan (TW); WEN-JANG JIANG, Chu-Nan (TW)

Correspondence Address: PCE INDUSTRY, INC.;ATT. Steven Reiss, 288 SOUTH MAYO AVENUE, CITY OF INDUSTRY, CA, 91789, US

(73) Assignee: FOXSEMICON INTEGRATED TECHNOLOGY, INC., Chu-Nan (TW)

(21) Appl. No.: 12/426,284

(22) Filed: Apr. 20, 2009

(30) Foreign Application Priority Data
Dec. 27, 2008 (CN) 200810306597.7

(51) Int. Cl. H01L 31/052

(52) U.S. Cl. 136/246

(57) ABSTRACT

An exemplary solar cell module includes a main body, a number of solar cells, and a reflective layer. The main body defines a concavity surface defined thereon. The solar cells are positioned at the concavity surface and generally symmetrically arranged with respect to a central axis of the concavity surface, configured for converting sunlight to electricity. The reflective layer is positioned on the concavity surface, with the solar cells exposed to an exterior of the main body corresponding to the concavity surface.

### BACKGROUND

1. Technical Field

The present invention relates to a solar cell module which has a concavity surface.

2. Description of the Related Art

Photovoltaic devices, i.e., solar cells, are capable of converting sunlight into usable electrical energy. The energy conversion occurs as the result of what is known as the photovoltaic effect. Sunlight striking a solar cell and absorbed by an active region of semiconductor material generates electricity.

A typical solar cell module includes a flat substrate and a number of solar cells installed on a plane of the flat substrate. The solar cells offer a clean and effectively inexhaustible source of energy. The more sunlight absorbed by the solar cells, the more electrical energy can be generated. Usually, the flat substrate of the solar cell module is fixed. However, the sun's position in the sky varies both with the seasons (latitude) and the time of day (elevation) as the sun moves across the sky, so the angle of incidence of the sunlight on the flat substrate changes from day to day and during each day. Thus, the solar cells cannot maintain a high absorption rate at all times. As a result, the efficiency of the solar cell module may be greatly reduced.

To overcome the disadvantages described above, solar trackers can be provided. One well-known type of solar tracker is the heliostat, a movable mirror that reflects the moving sun to a fixed location, such as the plane of the flat substrate. However, the solar tracker is somewhat expensive, and its use in solar energy applications is limited.

What is needed, therefore, is a solar cell module with high solar absorption efficiency.

### BRIEF DESCRIPTION OF THE DRAWINGS

Many aspects of the present solar cell module can be better understood with reference to the following drawings. The components in the drawings are not necessarily drawn to scale, the emphasis instead being placed upon clearly illustrating the principles of the present solar cell module. Moreover, in the drawings, like reference numerals designate corresponding parts throughout the several views.

FIG. 1 is a schematic, isometric view of a first exemplary embodiment of a solar cell module.

FIG. 2 is a cross-sectional view of the solar cell module of FIG. 1, taken along line II-II thereof.

FIG. 3 is a schematic, isometric view of a second exemplary embodiment of a solar cell module.

FIG. 4 is a cross-sectional view of the solar cell module of FIG. 3, taken along line IV-IV thereof.

FIG. 5 is a cross-sectional view of a third exemplary embodiment of a solar cell module.

Corresponding reference characters indicate corresponding parts throughout the drawings. The exemplifications set out herein illustrate at least one preferred embodiment of the present solar cell module, in one form, and such exemplifications are not to be construed as limiting the scope of the invention in any manner.

### DETAILED DESCRIPTION

Reference will now be made to the drawings to describe exemplary embodiments of the present solar cell module in detail.

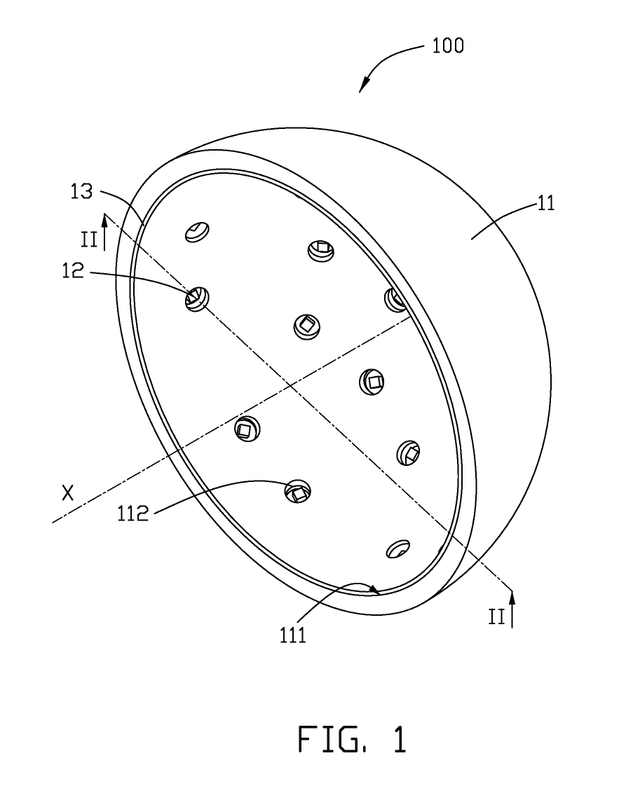

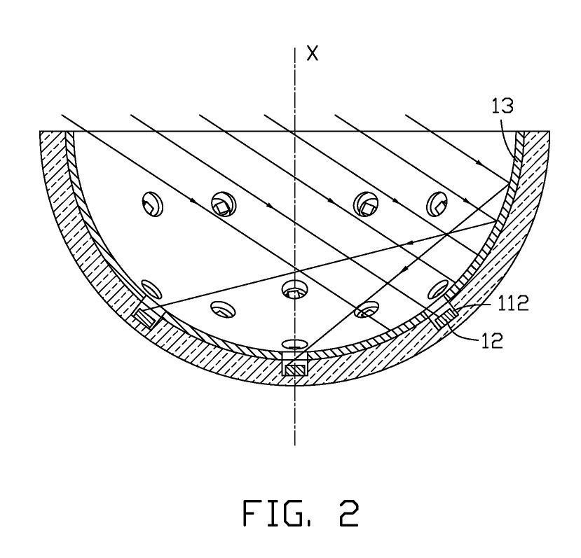

Referring to FIGS. 1 and 2, a solar cell module 100 in accordance with a first exemplary embodiment is shown. The solar cell module 100 includes a main body 11, a number of solar cells 12, and a reflective layer 13.

The main body 11 has a concavity surface 111 defined thereon. In the present embodiment, the main body 11 is hemispherical, and the concavity surface 111 is a hemispherical surface. The main body 11 includes a number of recesses 112 defined at the concavity surface 111, the recesses 112 extending into the main body 11. The recesses 112 are distributed generally symmetrically with respect to a central axis X of the concavity surface 111. In particular, one recess 112 is located at the inmost part of the concavity surface 111 on the central axis X. The other recesses 112 are distributed in groups on the concavity surface 111. In each group, the recesses 112 are generally radially symmetrical about a common nearest point on the central axis X. In one embodiment, for at least one of the groups, the recesses 112 are generally evenly distributed around the common nearest point on the central axis X. The material of the main body 11 can be, but is not limited to, metal or ceramic.

Each of the recesses 112 receives one solar cell 12 therein. The solar cells 12 may be III-V solar cells, which are configured for converting absorbed sunlight to electricity. It can be understood that in alternative embodiments, each of the recesses 112 may receive two or more solar cells 12 therein.

The reflective layer 13 is attached on the concavity surface 111 of the main body 11, so that all the recesses 112 are exposed. The reflective layer 13 is configured for reflecting incident sunlight. Typically, sunlight is incident on one side only of the reflective layer 13, and the reflective layer 13 reflects the sunlight to the solar cells 12 at the opposite side of the reflective layer 13. Thereby, the solar absorption efficiency of the solar cell module 100 can be improved under various conditions of ambient sunlight.

In FIG. 2, a part of the solar cell module 100 is exposed to the sun, and the rays of sunlight can be considered as parallel rays. The sunlight strikes part of the concavity of the solar cell module 100, and the solar cells 12 located at this part of the solar cell module 100 can directly receive the sunlight with high solar absorption efficiency. In addition, the reflective layer 13 at this part of the solar cell module 100 can reflect the sunlight to an opposite part of the solar cell module 100. That is, because the concavity surface 111 of the solar cell module 100 is a hemispherical surface, the solar cells 12 hidden from direct sunlight can still receive reflected sunlight from the reflective layer 13. Therefore, no matter what the sun's position in the sky is, most or all of the solar cells 12 can receive sunlight directly and/or indirectly. Thus, the solar absorption efficiency of the solar cell module 100 can be greatly improved. For similar reasons, when the solar cell module 100 is employed in a movable object such as a portable electronic device, the solar absorption efficiency of the solar cell module 100 can be greatly improved no matter how the portable electronic device is positioned in relation to incoming sunlight.

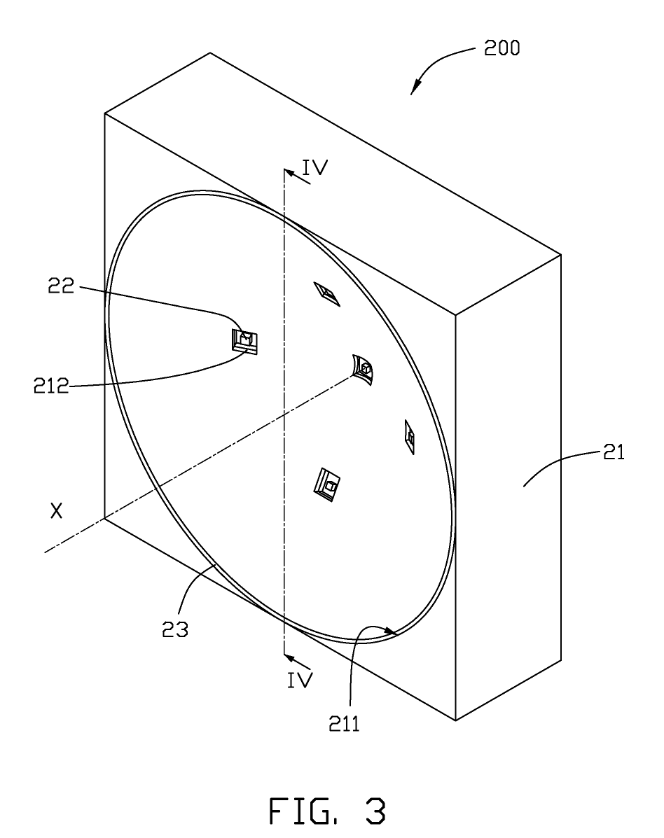

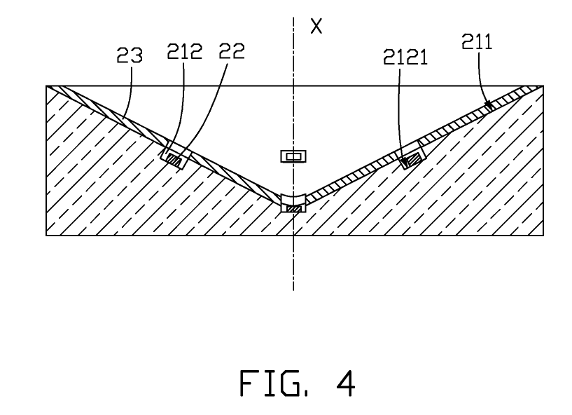

Referring to FIGS. 3 and 4, a solar cell module 200 in accordance with a second exemplary embodiment is shown. The solar cell module 200 includes a main body 21, a number of solar cells 22, and a reflective layer 23. The solar cell module 200 differs from the solar cell module 100 of the first exemplary embodiment in that the main body 21 is parallelepiped (generally block-shaped), and a concavity surface 211 is an essentially conical surface. In the illustrated embodiment, the conical surface is a circular conical surface.

In the present embodiment, the main body 21 includes a number of recesses 212 defined at the concavity surface 211, the recesses 212 extending into the main body 21. The recesses 212 are distributed generally symmetrically with respect to a central axis X of the concavity surface 211. In particular, one recess 212 is located at the inmost part of the concavity surface 211 on the central axis X. The other recesses 212 are distributed in groups on the concavity surface 211. In each group, the recesses 212 are generally radially symmetrical about a common nearest point on the central axis X. In the illustrated embodiment, there are two such groups of recesses 212. Each group has two recesses 212. The recesses 212 in one of the groups are symmetrically opposite each other and positioned corresponding to two opposite sides of the main body 21. The recesses 212 in the other group are symmetrically opposite each other and positioned corresponding to another two opposite sides of the main body 21. The four recesses 212 of the two groups cooperatively form a generally encircling arrangement about the central axis X. In addition, a bottom surface 2121 of each of the recess 212 is substantially parallel with the concavity surface 211, such that more sunlight can strike the solar cell 22 positioned in the recesses 212. Thereby, the solar absorption efficiency of the solar cells 22 can be improved.

The reflective layer 23 is attached on the concavity surface 211 of the main body 21, so that all the recesses 212 are exposed. The reflective layer 23 is configured for reflecting incident sunlight. Typically, sunlight is only incident on one side of the reflective layer 23, and the reflective layer 23 reflects the sunlight to the solar cells 22 at the opposite side of the reflective layer 23. Thereby, the solar absorption efficiency of the solar cell module 200 can be improved under various conditions of ambient sunlight. The sunlight strikes part of the concavity of the solar cell module 200, and the solar cells 22 located at this part of the solar cell module 200 can directly receive the sunlight with high solar absorption efficiency. In addition, the reflective layer 23 at this part of the solar cell module 200 can reflect the sunlight to an opposite part of the solar cell module 200. That is, because the concavity surface 211 of the solar cell module 200 is a conical surface, the solar cells 22 hidden from direct sunlight can still receive reflected sunlight from the reflective layer 23. Therefore, no matter what the sun's position in the sky is, the solar cells 22 can receive sunlight directly and/or indirectly. Thus, the solar absorption efficiency of the solar cell module 200 can be greatly improved. For similar reasons, when the solar cell module 200 is employed in a movable object such as a portable electronic device, the solar absorption efficiency of the solar cell module 200 can be greatly improved no matter how the portable electronic device is positioned in relation to incoming sunlight.

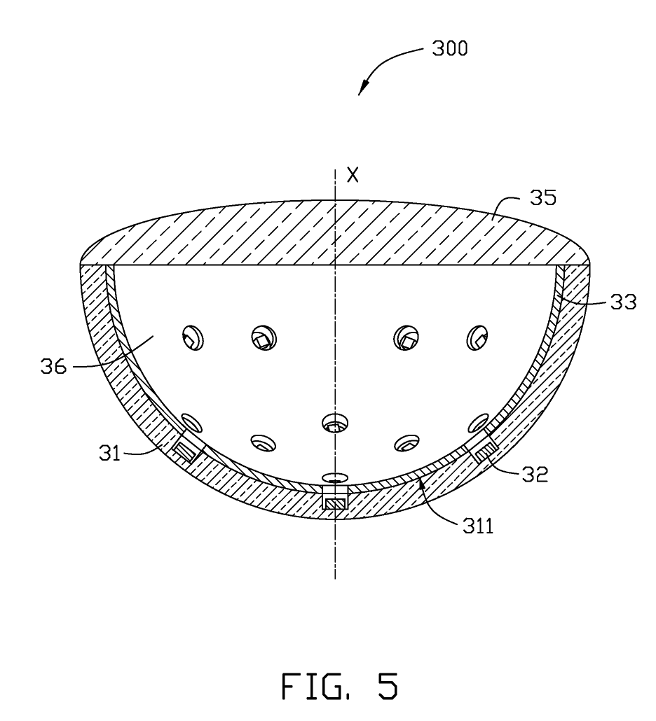

Referring to FIG. 5, a solar cell module 300 in accordance with a third exemplary embodiment is shown. The solar cell module 300 includes a main body 31, a number of solar cells 32, and a reflective layer 33. The main body 31 defines a concavity surface 311. The reflective layer 33 covers the concavity surface 311, except where the solar cells 32 are located. The solar cell module 300 differs from the solar cell module 100 of the first exemplary embodiment in that the solar cell module 300 further includes a concentrating lens 35. The concentrating lens 35 is positioned on a top (front) face of the main body 31, and covers the reflective layer 33 to form a vacuum cavity 36 in the main body 31. The concentrating lens 35 is configured for collecting sunlight and redirecting it to the solar cells 32, to further improve the amount of sunlight directly striking the solar cells 32.

It is to be understood that the above-described embodiments are intended to illustrate rather than limit the invention. Variations may be made to the embodiments without departing from the spirit of the invention as claimed. The above-described embodiments are intended to illustrate the scope of the invention and not restrict the scope of the invention.

What is claimed is:

1. A solar cell module, comprising:
a main body defining a concavity surface;
a plurality of solar cells positioned at the concavity surface and generally symmetrically arranged with respect to a central axis of the concavity surface, the solar cells configured for converting sunlight to electricity; and
a reflective layer positioned on the concavity surface, with the solar cells exposed to an exterior of the main body corresponding to the concavity surface.

2. The solar cell module of claim 1, wherein the main body further comprises a plurality of recesses defined at the concavity surface, with the recesses extending into the main body, and the recesses are distributed generally symmetrically with respect to a central axis of the concavity surface and respectively receive the solar cells therein.

3. The solar cell module of claim 2, wherein one recess is located at the inmost part of the concavity surface on the central axis, the other recesses are distributed in at least one group on the concavity surface, and the recesses of each group of said at least one group are generally radially symmetrical about a common nearest point on the central axis.

4. The solar cell module of claim 3, wherein for at least one group of said at least one group, the recesses are generally evenly distributed around the common nearest point on the central axis.

5. The solar cell module of claim 3, wherein the recesses of at least one group of said at least one group cooperatively form a generally encircling arrangement about the central axis.

6. The solar cell module of claim 2, wherein a bottom surface of each of the recesses is substantially parallel with the concavity surface.

7. The solar cell module of claim 1, wherein the concavity surface is a hemispherical surface.

8. The solar cell module of claim 1, wherein the concavity surface is an essentially conical surface.

9. The solar cell module of claim 1, wherein the main body is one of hemispherical and parallelepiped.

10. The solar cell module of claim 1, wherein material of the main body is selected from the group consisting of metal and ceramic.

11. The solar cell module of claim 1, further comprising a concentrating lens positioned on a face of the main body and covering the reflective layer to form a vacuum cavity in the main body.

12. A solar cell module, comprising:
a main body defining a hollow, and having a curved surface bounding the hollow;
a plurality of solar cells positioned at the curved surface, and being generally symmetrically arranged with respect to a central axis of the curved surface, the solar cells configured for converting sunlight to electricity; and
a reflective layer positioned on the curved surface, with the solar cells exposed to an exterior of the main body beyond the hollow.

13. The solar cell module of claim 12, wherein the main body further defines a plurality of recesses defined at the curved surface, with the recesses extending into the main body, and the recesses are distributed generally symmetrically with respect to a central axis of the curved surface and respectively receive the solar cells therein.

14. The solar cell module of claim 13, wherein one of the recesses is located at the inmost part of the curved surface on the central axis, the other recesses are distributed in at least one group on the curved surface, and the recesses of each group of said at least one group are generally radially symmetrical about a common nearest point on the central axis.

15. The solar cell module of claim 14, wherein for at least one group of said at least one group, the recesses are generally evenly distributed around the common nearest point on the central axis.

16. The solar cell module of claim 14, wherein the recesses of at least one group of said at least one group cooperatively form a generally encircling arrangement about the central axis.

17. The solar cell module of claim 12, wherein a bottom surface of each of the recesses is substantially parallel with the curved surface.

18. The solar cell module of claim 12, further comprising a concentrating lens positioned on a face of the main body and covering the reflective layer to form a vacuum cavity in the main body.

19. The solar cell module of claim 12, wherein the curved surface is one of a hemispherical surface and an essentially conical surface.
